(19) United States
(12) Patent Application Publication
(10) Pub. No.: US 2007/0148348 A1
(43) Pub. Date: Jun. 28, 2007

(54) Evaporation source and method of depositing thin film using the same

(76) Inventors: Myung Soo Huh, Suwon-si (KR); Kazuo Furuno, Suwon-si (KR); Sang Jin Han, Suwon-si (KR); Jae Hong Ahn, Suwon-si (KR); Seok Heon Jeong, Yongin-si (KR)

Correspondence Address: LEE & MORSE, P.C., 3141 FAIRVIEW PARK DRIVE, SUITE 500, FALLS CHURCH, VA, 22042, US

(21) Appl. No.: 11/583,930

(22) Filed: Oct. 20, 2006

(30) Foreign Application Priority Data
Dec. 28, 2005 (KR) 2005-0131489

(51) Int. Cl. C23C 16/00

(52) U.S. Cl. 427/248.1; 427/255.6; 118/726

(57) ABSTRACT

An evaporation source and method for depositing a thin film, including a crucible having a predetermined space for placing a deposition material and at least one baffle, the baffle positioned inside the crucible and parallel to the predetermined space to divide the crucible into a plurality of channels, a heating unit, and at least one spray nozzle in fluid communication with the crucible, the spray nozzle having a plurality of spray orifices.

### BACKGROUND OF THE INVENTION

1. Field of the Invention

The present invention relates to an evaporation source and a method for depositing thin films using the same. In particular, the present invention relates to an evaporation source and method for depositing thin films capable of providing uniform film thickness and minimized heat radiation.

2. Discussion of the Related Art

Deposition of thin films has numerous manufacturing applications. In semiconductor manufacturing, for example, thin films may be deposited in display devices, such as electroluminescent (EL) display devices, to provide photon-emitting mediums to form images.

Such thin films may be applied to a substrate, e.g., an electrode, by methods such as physical vapor deposition (PVD), e.g., vacuum deposition, chemical vapor deposition (CVD), ion plating, sputtering, and so forth. In the vacuum deposition method, for example, a vacuum environment, e.g., vacuum chamber, may be provided with a substrate. An evaporation source having a heating unit and a deposition material, e.g., organic light-emitting material, may be either connected to the vacuum environment or installed therein, such that the operation of the evaporation source may evaporate the deposition material and form a thin film on the substrate.

An evaporation source may include a crucible to contain a deposition material, a heating unit to heat the crucible and evaporate the deposition material, and at least one spray nozzle to apply the evaporated deposition material to a substrate.

However, the particles of the evaporated deposition material may have a tendency to coalesce and form clusters of particles having various sizes, thereby providing an evaporated deposition material having non-uniform texture and density consistency. Further, such non-uniform evaporated deposition material may cause application of non-uniform layers of deposition material onto substrates, thereby producing films lacking uniform thickness.

Additionally, application of the evaporated deposition material through a conventional spray nozzle onto a substrate may radiate excess heat into a processing chamber, thereby deforming the substrate upon contact therewith.

Further, application of deposition material to a rotatable substrate may require a large size of a processing chamber in order to accommodate sufficient space for substrate movement. Such large substrates may also sag or collapse as a result of upward application of deposition material thereon.

Accordingly, there remains a need for an evaporation source and a method of using the same providing thin films having uniform thickness, while minimizing excess heat radiation and processing chamber size.

### SUMMARY OF THE INVENTION

The present invention is therefore directed to an evaporation source and method of employing the same, which substantially overcome one or more of the disadvantages of the related art.

It is therefore a feature of an embodiment of the present invention to provide an evaporation source and a method employing the same having the capability of minimizing the coalescence of the evaporated deposition material, thereby improving uniformity of thin deposition layers.

It is another feature of an embodiment of the present invention to provide an evaporation source and a method employing the same having a nozzle structure with improved heat radiation distribution, thereby minimizing excessive heat transfer into a processing chamber.

It is yet another feature of an embodiment of the present invention to provide an evaporation source and a method employing the same, providing reduced size of processing chamber and substrate.

At least one of the above and other features and advantages of the present invention may be realized by providing an evaporation source, including a crucible having a predetermined space for placing a deposition material and at least one baffle, the baffle positioned inside the crucible and parallel to the predetermined space to divide the crucible into a plurality of channels, a heating unit, and at least one spray nozzle in fluid communication with the crucible, the spray nozzle having a plurality of spray orifices.

The baffle may include a plurality of baffle plates. Preferably, the baffle may include at least three parallel baffle plates. The crucible may include an induction channel. The deposition material may be an organic light-emitting material.

The evaporation source may also include a deposition rate measuring unit. Additionally, the evaporation source may include at least one reflector positioned between the heating unit and a housing wall of the evaporation source. Further, the evaporation source may include an insulating plate, while the spray nozzle may protrude through the insulating plate. The evaporation source may be movable.

According to another aspect of the present invention, there is provided a method of depositing a thin film, including providing an evaporation source having a heating unit, at least one spray nozzle, and a crucible with at least one baffle into a processing chamber, placing a substrate in the processing chamber, such that a surface of the substrate to be coated is facing the evaporation source, activating the heat unit, such that a deposition material in the crucible is evaporated, passing the evaporated deposition material through the baffle of the crucible to form a uniform deposition fluid, and spraying the uniform deposition fluid through the spray nozzle onto the substrate to form a thin film.

Passing the evaporated deposition material through a baffle may include passing the deposition material through a plurality of baffle plates.

Activating the heating unit may include evaporating an organic light-emitting material. Spraying the uniform deposition fluid may include moving the evaporation source. The inventive method may also include operating a deposition rate measuring unit. Additionally, the method may include providing a vacuum environment in the processing chamber.

### BRIEF DESCRIPTION OF THE DRAWINGS

The above and other features and advantages of the present invention will become more apparent to those of ordinary skill in the art by describing in detail exemplary embodiments thereof with reference to the attached drawings, in which:

FIG. 1 illustrates a perspective view of an apparatus for depositing a thin films using an evaporation source according to an embodiment of the present invention;

FIG. 2A illustrates a cross-sectional view of an evaporation source according to an embodiment of the present invention taken along the line I-I′ of FIG. 1;

FIG. 2B illustrates a cross-sectional view of a direction of movement of an evaporated deposition material inside an evaporation source according to an embodiment of the present invention taken along the line I-I′ of FIG. 1;

FIG. 3A illustrates a plan view of an evaporation source according to an embodiment of the present invention taken along the line II-II′ of FIG. 1; and

FIG. 3B illustrates a plan view of a direction of movement of an evaporated deposition material inside an evaporation source having a shower head structure according to an embodiment of the present invention taken along the line II-II′ of FIG. 1.

### DETAILED DESCRIPTION OF PREFERRED EMBODIMENTS

Korean Patent Application No. 2005-0131489, filed on Dec. 28, 2005, in the Korean Intellectual Property Office, and entitled: “Evaporation Source and Method of Depositing Thin Film Using the Same,” is incorporated by reference herein in its entirety.

The present invention will now be described more fully hereinafter with reference to the accompanying drawings, in which exemplary embodiments of the invention are illustrated. The invention may, however, be embodied in different forms and should not be construed as limited to the embodiments set forth herein. Rather, these embodiments are provided so that this disclosure will be thorough and complete, and will fully convey the scope of the invention to those skilled in the art.

In the figures, the dimensions of layers and elements may be exaggerated for clarity of illustration. It will also be understood that when a layer or element is referred to as being “on” another layer, element, or substrate, it can be directly on the other layer, element, or substrate, or intervening layers/elements may also be present. Further, it will be understood that when a layer or element is referred to as being “under” another layer or element, it can be directly under, or one or more intervening layers or elements may also be present. In addition, it will also be understood that when a layer or element is referred to as being “between” two layers or elements, it can be the only layer or element between the two layers/elements, or one or more intervening layers or elements may also be present. Like reference numerals refer to like elements throughout.

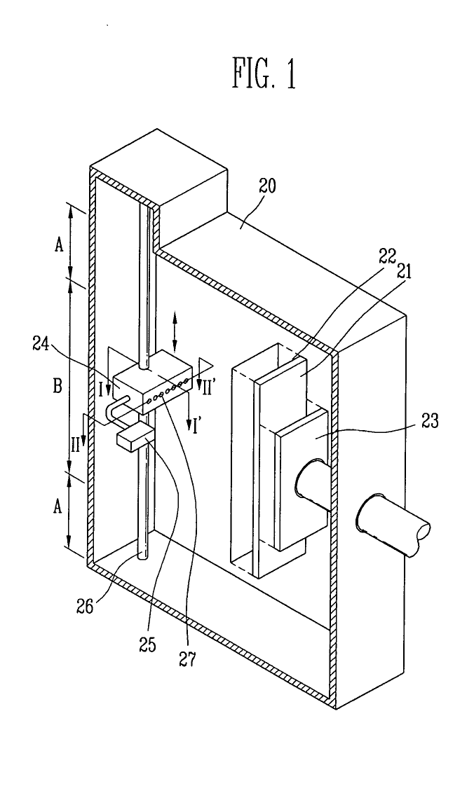

An exemplary embodiment of an apparatus containing an evaporation source in accordance with the present invention will now be more fully described with reference to FIG. 1.

As illustrated in FIG. 1, an apparatus for depositing thin films according to an embodiment of the present invention may include a processing chamber 20, a supporting unit 23 for securing a substrate, an evaporation source 24, and a deposition rate measuring unit 26 coupled to the evaporation source 24.

The processing chamber 20 of an embodiment of the present invention may be any type of vessel known by those skilled in the art for use in film processing, and, preferably, it may be a pressure-controlled vessel such as a vacuum chamber. The processing chamber 20 may be formed to have a deposition preventing part A and a film forming part B.

The film forming part B, as illustrated in FIG. 1, may refer to the central area of the processing chamber 20. The central area of the processing chamber 20 may correspond to a position where a substrate may be placed and formation of a film, e.g., vacuum deposition processing, may occur. The deposition preventing part A, as illustrated in FIG. 1, may refer to the area inside the processing chamber 20 that surrounds the film forming part B. In other words, the deposition preventing part A may be formed as peripheral portions of film forming part B. The peripheral portions, i.e., deposition preventing part A, may be excluded from film deposition processing. The deposition preventing part A may include a heat absorbing plate (not shown) formed around a substrate to remove excess heat from the substrate and provide uniform temperature and uniform film thickness.

For example, as illustrated in FIG. 1, a substrate 21 and a mask 22 may be placed in the processing chamber 20. In particular, the substrate 21 and mask 22 may be placed in the center of the processing chamber 20, i.e., film forming part B, such that the deposition preventing part A surrounds them. The mask 22 may be attached to the substrate 21 between the substrate 21 and the evaporation source 24. The mask 22 may include a pattern formation unit (not shown) having a pattern corresponding to a pattern to be imparted to a thin film formed on the substrate 21, and a fixation unit (not shown) secured to a mask frame (not shown) through welding.

The supporting unit 23 of an embodiment of the present invention may be coupled to the processing chamber 20 in order to secure the substrate 21 and the mask 22 in the film forming part A of the processing chamber 20, as illustrated in FIG. 1. The supporting unit 23 may be formed, for example, as a longitudinal member connected to the processing chamber 20 at one end and to a substrate at the other end, such that a substrate may be stably secured in its position. Additionally, an alignment system (not shown) may be added to align the substrate 21 and the mask thereon.

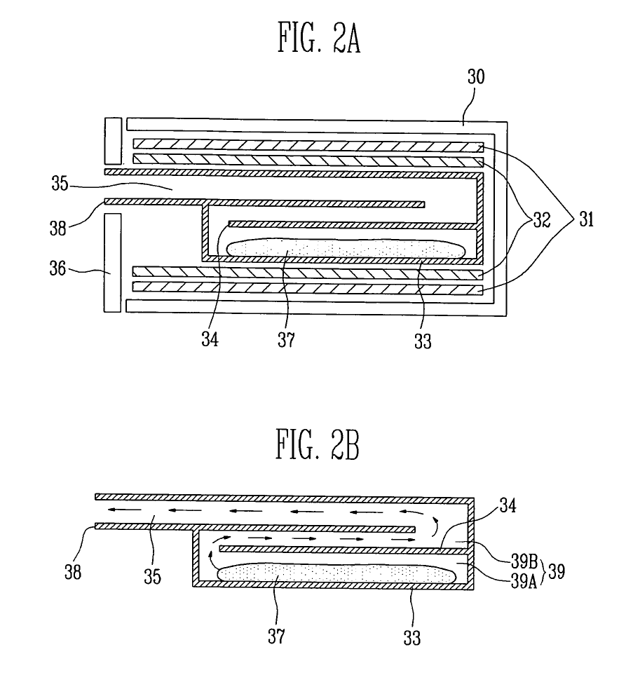

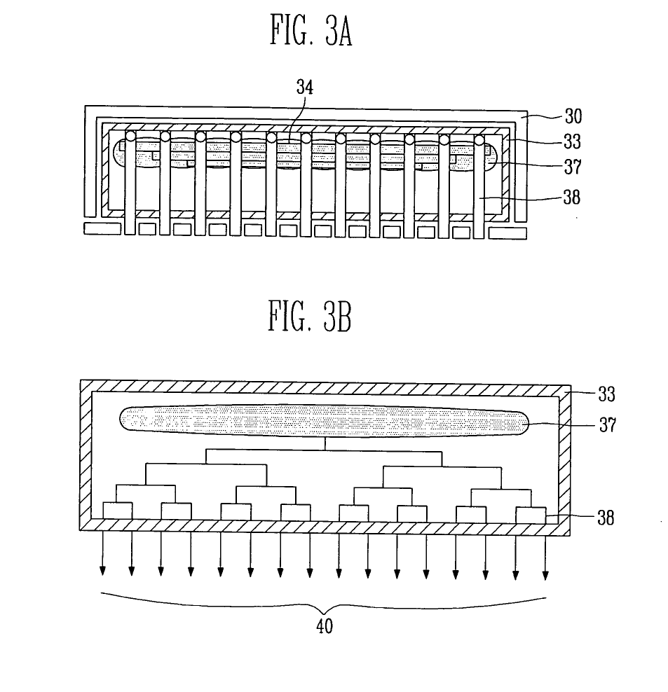

The evaporation source 24 of an embodiment of the present invention may supply sufficient heat to evaporate a deposition material placed therein, and, subsequently, apply it to a substrate in order to form a thin film. The detailed structure of the evaporation source 24 will be described in more detail with respect to FIGS. 2A-3B.

The evaporation source 24 of an embodiment of the present invention may include a crucible 33 for storing a deposition material 37, a heating unit 32 for evaporating the deposition material 37, at least one spray nozzle 38 for spraying the deposition material 37 onto the substrate 21, and a baffle 34 inside the crucible 33. The above mentioned components may be enclosed by a housing 30.

The crucible 33 may be formed to include a predetermined space for containing the deposition material 37 to be deposited onto the substrate 21, and it may be formed of any material known in the art that has excellent heat conductivity. In particular, the crucible 33 may be formed of a ceramic material, e.g., graphite, silicon carbide (SiC), aluminum nitride (AlN), alumina (Al₂O₃), boron nitride (BN), quartz, and so forth, or of a metal, e.g., titanium (Ti), stainless steel, and so forth.

The crucible 33 may further include at least one baffle 34. The baffle 34 in accordance with an embodiment of the present invention may be formed inside the crucible 33 in a form of at least one longitudinal baffle plate, as illustrated in FIGS. 2A-2B. The baffle 34 may be formed of any suitable material known in the art, and it may be positioned parallel to the predetermined space containing the deposition material 37 to divide the crucible into a plurality of channels 39, as further illustrated in FIGS. 2A-2B. The plurality of channels 39 may include at least two channels that form a movement path for the evaporated deposition material 37 from the crucible 33 to the induction channel 35.

The baffle 34 may also include a plurality of baffle plates, e.g., three baffle plates 34A, 34B, and 34C, as shown in FIG. 3A, arranged parallel to each other throughout the width of the crucible 33 in such a way that a labyrinth may be formed along the path of movement of the evaporated deposition material 37, as illustrated in FIGS. 2B and 3A.

Without intending to be bound by theory, it is believed that, when the crucible 33 is heated by the heating unit 32, the deposition material 37 may evaporate and flow from the crucible 33 through the baffle 34 and the plurality of channels 39 towards the induction channel 35. The flow of the evaporated deposition material 37 may collide with the baffle 34 and, thereby, enhance break-up of any coalesced clusters of the evaporated deposition material 37. Such cluster break-up may enhance the uniformity of the evaporated deposition material in terms of texture and density, i.e., the evaporated deposition material may include particles having substantially similar dimensions.

The deposition material 37 may be any type of material employed in the art for forming thin films in display devices. For example, the deposition material may be a light-emitting material or, more preferably, an organic light-emitting material.

The heating unit 32 may include at least one heater (not shown). Preferably, the evaporation source 24 may include a plurality of heating units 32, each heating unit 32 having at least one electrical heater (not shown). As such, the heating unit 32 may be formed in close proximity to the crucible 33 to provide sufficient heat to evaporate the deposition material 37 contained therein. Preferably, a heating unit 32 may be formed on each horizontal side of the crucible 33, as illustrated in FIG. 2A.

At least one reflector 31 may be provided between each heating unit 32 and the housing 30 surrounding the crucible 33. Preferably, the evaporation source 24 may include a plurality of reflectors 31 formed in close proximity to the heating units 32 to reflect heat emitted from the heating units 32 into the crucible 33, thereby minimizing heat leakage outside the evaporation source 24.

The spray nozzle 38 may be formed in the housing 30, and, preferably, the spray nozzle 38 may protrude through the housing 30. The spray nozzle 38 may be connected to an induction channel 35, which may direct the deposition material 37 from the crucible 33 into the nozzle 38, as illustrated in FIG. 2B. Additionally, the spray nozzle 38 may have a shower head structure, as illustrated in FIG. 3B. In other words, the spray nozzle 38 may include a plurality of nozzle orifices 40 formed through the housing 30, such that application of the evaporated deposition material 37 through the plurality of nozzle orifices 40 may be simultaneous and uniform. As further illustrated in FIG. 3B, the plurality of nozzle orifices 40 may be in fluid communication with the deposition material 37 through a plurality of channels.

Without intending to be bound by theory, it is believed that application of the evaporated deposition material 37 through the shower head structure of the spray nozzles 38 may distribute the heat generated in the crucible 33 over a larger surface area during application, thereby reducing the amount of heat released from the crucible 33 into the process chamber 20 and the substrate 21, and further minimizing deformation of the substrate 21 and the mask 22 due to excess heat.

The housing 30 may be formed to include a double wall having an internal wall (not shown) and an external wall (not shown). The double wall structure may provide sufficient space between the internal and external walls for cooling water to facilitate temperature control.

The evaporation source 24 of an embodiment of the present invention may also include an insulating plate 36 between the crucible 33 and the inside wall of the housing 30. The insulating plate 36 may minimize heat transfer from the induction channel 35 into the processing chamber 20 and the substrate 21.

The evaporation source 24 according to an embodiment of the present invention may be moveable. In particular, the evaporation source 24 may be formed on a driving shaft 26. The driving shaft 26 may be formed parallel to the longitudinal side of the substrate 21 inside the processing chamber 20. The driving shaft 26 may also include a rotary unit (not shown) that may rotate and move the evaporation source 24 along the driving shaft 26, such that the evaporation unit 24 may move up and down along the driving shaft 26 in a direction perpendicular to the direction of the rotation of the driving shaft 26. In this regard, it should be noted that without intending to be bound by theory, it is believed that employing a movable evaporation source 24 may reduce the size of the processing chamber 20 by at least about 75% as compared to a size of a processing chamber having a stationary evaporation source and a rotatable substrate.

The evaporation source 24 of an embodiment of the present invention may further include a deposition rate measuring unit 25. The deposition rate measuring unit 25 may be affixed to the evaporation source 24, such that the deposition rate measuring unit 25 and the evaporation source 24 may move jointly. The deposition rate measuring unit 25 may also be integral to the evaporation source 24. The joint motion of the deposition rate measuring unit 25 and the evaporation source 24, whether integrated or not, may allow continuous real-time measurement of the evaporation rate of the deposition material and control of its deposition rate onto the substrate 21.

The deposition rate measuring unit 25 may also have the capability of adjusting the evaporation rate of the deposition material in order to achieve a specific deposition rate onto a substrate. For example, the deposition rate measuring unit 25 may be electrically connected to the heating unit 32 of the evaporation source 24, such that the heat amount generated for evaporating the deposition material 37 in the evaporation source 24 may be increased or decreased with respect to a desired deposition rate. Similarly, the deposition rate measuring unit 25 may be electrically connected to the rotary unit of the driving shaft 26, such that the speed at which the evaporation source 24 moves may be increased or decreased with respect to the generated amount of the evaporated deposition material 37. The control of the evaporation source 24 speed may facilitate control of the exposure time of the substrate 21 to the evaporation source 24, i.e., deposition rate.

According to another aspect of the present invention, an exemplary method of depositing a thin film onto a substrate is described below with reference to FIGS. 1-2B.

The substrate 21 may be placed in the processing chamber 20, e.g., a vacuum chamber, and secured therein with the supporting unit 23. The mask 22 may be attached to the surface of the substrate 21 to be coated. Next, the evaporation source 24 having a heating unit 32, a crucible 33, a baffle 34, and a spray nozzle 38 with a shower head structure may be provided in the processing chamber 20, such that the evaporation source 24 may face the surface of the substrate 21 to be coated.

Once the processing chamber 20 is set, a deposition material 37, e.g., a metal or a light-emitting material such as an organic light-emitting material employed in manufacturing of organic-light emitting diodes (OLEDs), may be placed in the crucible 33 of the evaporation source 24.

The heating unit 32 of the evaporation source 24 may be activated to heat the crucible 33, such that the deposition material 37 placed therein is evaporated, e.g., gasified or sublimated. The evaporated deposition material 37 may be passed through at least one baffle plate of the baffle 34 to form a uniform deposition fluid having substantially uniform texture and density, and the uniform deposition fluid may continue through a plurality of channels 39 into the induction channel 35, and, subsequently, into the spray nozzle 38. Preferably, the evaporation temperatures in the evaporation source 24 may be low, i.e., temperatures ranging from about 200° C. to about 400° C.

The evaporated deposition material 37 may be applied to the substrate 31 by any means known in the art, e.g., spraying. Spraying may be done, for example, by dispersion of the evaporated deposition material 37 through the shower head structure of the spray nozzle 38, such that only the heat generated in the crucible 33 by the evaporation process, i.e., heat generated due to enthalpy of evaporation of the deposition material 37, as opposed to heat produced by the heating unit 32, may be released, thereby providing improved control of the heat reaching the substrate 21. The deposition rate may also be adjusted, as previously discussed with respect to the operation of the deposition rate measuring unit 25, in order to control the thickness and uniformity of the thin film and provide reproducibility of injected impurities. Once the deposition material is successfully applied to the substrate 21, it may solidify to form a thin film.

Exemplary embodiments of the present invention have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. An evaporation source, comprising:
a crucible including a predetermined space for placing a deposition material and at least one baffle, the baffle positioned inside the crucible and parallel to the predetermined space to divide the crucible into a plurality of channels;
a heating unit; and
at least one spray nozzle in fluid communication with the crucible, the spray nozzle having a plurality of spray orifices.

2. The evaporation source as claimed in claim 1, wherein the baffle comprises a plurality of baffle plates.

3. The evaporation source as claimed in claim 2, wherein the plurality of baffle plates comprises at least three parallel baffle plates.

4. The evaporation source as claimed in claim 1, wherein the crucible further comprises an induction channel.

5. The evaporation source as claimed in claim 1, further comprising a deposition rate measuring unit.

6. The evaporation source as claimed in claim 1, further comprising at least one reflector positioned between the heating unit and a housing wall of the evaporation source.

7. The evaporation source as claimed in claim 1, further comprising an insulating plate.

8. The evaporation source as claimed in claim 7, wherein the spray nozzle protrudes through the insulating plate.

9. The evaporation source as claimed in claim 1, wherein the evaporation source is movable.

10. The apparatus as claimed in claim 1, wherein the deposition material is an organic light-emitting material.

11. A method of depositing a thin film, comprising:
providing an evaporation source including a heating unit, at least one spray nozzle, and a crucible with at least one baffle into a processing chamber;
placing a substrate in the processing chamber, such that a surface of the substrate to be coated is facing the evaporation source;
activating the heat unit, such that a deposition material in the crucible is evaporated;
passing the evaporated deposition material through the baffle of the crucible to form a uniform deposition fluid; and
spraying the uniform deposition fluid through the spray nozzle onto the substrate to form a thin film.

12. The method as claimed in claim 11, wherein passing the evaporated deposition material through a baffle comprises passing the evaporated deposition material through a plurality of baffle plates.

13. The method as claimed in claim 11, further comprising operating a deposition rate measuring unit.

14. The method as claimed in claim 11, wherein spraying the uniform deposition fluid comprises moving the evaporation source.

15. The method as claimed in claim 11, wherein activating the heating unit comprises evaporating an organic light-emitting material.

16. The method as claimed in claim 11, further comprising providing a vacuum environment in the processing chamber.
